(19) United States
(12) Patent Application Publication
(10) Pub. No.: US 2026/0191073 A1
(43) Pub. Date: Jul. 2, 2026

(54) METHOD FOR PRODUCING CIRCUIT CONNECTION STRUCTURE, AND CIRCUIT CONNECTION DEVICE

(71) Applicant: Resonac Corporation, Tokyo (JP)

(72) Inventors: Tomoki MORIJIRI, Tokyo (JP); Hiroyuki IZAWA, Tokyo (JP); Mayumi SATO, Tokyo (JP); Yuka ITOH, Tokyo (JP)

(21) Appl. No.: 18/855,739

(22) PCT Filed: May 18, 2023
(86) PCT No.: PCT/JP2023/018615

§ 371 Date: Oct. 10, 2024

(30) Foreign Application Priority Data
May 31, 2022 (JP) 2022-088582

(51) Int. Cl. H10W 72/00

(52) U.S. Cl. CPC H10W 72/07532; H10W 72/07141; H10W 72/07152; H10W 72/07537

(57) ABSTRACT

A method for manufacturing a circuit connection structure includes: disposing a circuit connection material including a solder connection material and an adhesive on a surface of a first circuit member having the first electrode; disposing a second circuit member having a second electrode on the first circuit member thermally compressing the first and the second circuit member at a temperature equal to or higher than a melting point of the solder connection material in a state in which the solder connection material is interposed between the first and the second electrode; and cooling while applying a pressure between the first and the second electrode until a temperature between the first and the second electrode becomes a temperature equal to or lower than the above melting point from a temperature equal to or higher than the above melting point.

### TECHNICAL FIELD

The present disclosure relates to a method for manufacturing a circuit connection structure, and a circuit connection device.

### BACKGROUND ART

In fields of a semiconductor, a liquid crystal monitor, and the like, solder has been used as a connection material that connects electrodes of a circuit member such as a semiconductor chip and a circuit substrate. For example, Patent Literature 1 discloses a method of forming a solder bump that is used to connect a semiconductor device to a substrate by flip-chip mounting or the like.

### CITATION LIST

### Patent Literature

Patent Literature 1: Japanese Unexamined Patent Publication No. 2017-157626

### SUMMARY OF INVENTION

### Technical Problem

The circuit connection using solder is performed by a method of heating solder at a high temperature by using a reflow furnace or the like to melt the solder and cause the solder to be eutectic. However, there are growing needs for a circuit connection method that requires less energy due to the recent rise in global awareness toward a recycling-oriented society such as carbon neutrality, green orientation, and SDGs and promotion of environment-related investments.

As one method of performing the circuit connection by solder with less energy, there is a method of manufacturing a circuit connection structure by compressing (that is, thermally compressing) circuit members disposed to face each other through solder while heating the circuit members. According to this method, the circuit members can be connected at a relatively low temperature.

However, in the above-described method, a minute crack is likely to occur in an inter-electrode connection portion (solder connection portion) of the circuit connection structure, and a failure such as a deterioration of connection reliability is likely to occur due to the crack.

Here, an object of one aspect of the present disclosure is to reduce a crack of an inter-electrode connection portion which occurs when using solder as a connection material between facing electrodes in a method for manufacturing a circuit connection structure by thermally compressing circuit members.

### Solution to Problem

Several aspects of the present disclosure provide the following [1] to [6].

[1]A method for manufacturing a circuit connection structure, including:
a step (a) of disposing a circuit connection material including a solder connection material and an adhesive on a surface, on which a first electrode is formed, of a first circuit member having the first electrode;
a step (b) of disposing a second circuit member having a second electrode on the first circuit member so that the first electrode and the second electrode face each other;
a step (c) of thermally compressing the first circuit member and the second circuit member at a temperature equal to or higher than a melting point of the solder connection material in a state in which the solder connection material is interposed between the first electrode and the second electrode; and
a step (d) of cooling while applying a pressure between the first electrode and the second electrode until a temperature between the first electrode and the second electrode becomes a temperature equal to or lower than the melting point of the solder connection material from a temperature equal to or higher than the melting point of the solder connection material.

[2] The method for manufacturing a circuit connection structure according to [1],
wherein the solder connection material is a solder particle.

[3] The method for manufacturing a circuit connection structure according to [2],
wherein in the step (a), the circuit connection material is disposed on the first circuit member in a state of film containing the solder particle and the adhesive.

[4] The method for manufacturing a circuit connection structure according to [2],
wherein in the step (a), the circuit connection material is disposed on the first circuit member in a state of paste containing the solder particle and the adhesive.

[5] The method for manufacturing a circuit connection structure according to any one of [1] to [4],
wherein the melting point of the solder connection material is 300° C. or lower, and
the thermal compression temperature in the step (c) is 330° C. or lower.

[6]A circuit connection device that is used in the method for manufacturing a circuit connection structure according to any one of [1] to [5], including:
a stage on which the first circuit member or the second circuit member is mounted;
a pressing unit configured to press the first circuit member and the second circuit member in a direction of facing each other;
a heating unit configured to heat at least one of the first circuit member and the second circuit member; and
a cooling unit configured to cool between the first electrode and the second electrode in the step (d).

### Advantageous Effects of Invention

According to one aspect of the present disclosure, it is possible to reduce a crack of an inter-electrode connection portion which occurs when using solder as a connection material between facing electrodes in a method for manufacturing a circuit connection structure by thermally compressing circuit members.

### BRIEF DESCRIPTION OF DRAWINGS

FIG. 1 is a cross-sectional view schematically illustrating a step (a) to a step (c) of a method for manufacturing a circuit connection structure according to one embodiment.

FIG. 2 is a cross-sectional view schematically illustrating a step (d) of the method for manufacturing a circuit connection structure according to one embodiment.

FIG. 3 is a cross-sectional view schematically illustrating a method for manufacturing a circuit connection structure according to another embodiment.

FIG. 4 is a view illustrating a temperature-pressure profile of Example 1.

FIG. 5 is a view illustrating a temperature-pressure profile of Comparative Example 1.

FIG. 6 is a view illustrating a temperature-pressure profile of Comparative Example 2.

### DESCRIPTION OF EMBODIMENTS

In this specification, a numerical value range indicated by using “to” represents a range including numeral values described before and after “to” as a minimum value and a maximum value, respectively. In addition, units the numerical values described before and after “to” are the same as each other unless otherwise specified. In a numerical value range described step by step in this specification, an upper limit value or a lower limit value of a numerical value range of any step may be substituted with an upper limit value or a lower limit value of a numerical value range of another step. In a numerical value range described in this specification, an upper limit value or a lower limit value of the numerical value range may be substituted with a value shown in an example.

Hereinafter, embodiments of the present disclosure will be described in detail with reference to the accompanying drawings as necessary. However, the present disclosure is not limited to the following embodiments.

A method for manufacturing a circuit connection structure of one embodiment includes a step (a) of disposing a circuit connection material including a solder connection material and an adhesive on a surface, on which a first electrode is formed, of a first circuit member having the first electrode, a step (b) of disposing a second circuit member having a second electrode on the first circuit member so that the first electrode and the second electrode face each other, a step (c) of thermally compressing the first circuit member and the second circuit member at a temperature (thermal compression temperature) equal to or higher than a melting point of the solder connection material in a state in which the solder connection material is interposed between the first electrode and the second electrode, and a step (d) of cooling while applying a pressure between the first electrode and the second electrode until a temperature between the first electrode and the second electrode becomes a temperature equal to or lower than the melting point of the solder connection material from a temperature equal to or higher than the melting point of the solder connection material. The method for manufacturing a circuit connection structure may further include a step (e) of cooling without applying a pressure between the first electrode and the second electrode.

In the manufacturing method, it is possible to obtain a circuit connection structure with reduced cracks between electrodes, that is, cracks in the solder connection portion which are formed when a melted solder connection material is cooled and solidified. The reason for this is inferred as follows.

First, in a conventional method using a solder connection material, a heating and pressing tool is pressed against a circuit member, and the circuit member is heated and pressed at the same time for thermal compression, and then the heating and pressing tool is separated from the circuit member, and thus pressing and heating between the electrodes are substantially terminated. In the method, it is inferred that since a pressure applied between the electrodes is released before the solder connection material melted by the thermal compression is cooled and solidified, a stress in a direction opposite to the facing direction is applied to the melted solder connection material during pressure release, and thus cracks occur. On the other hand, according to the above-described manufacturing method, it is inferred that since the pressure between the electrodes is released after the solder connection material melted by the thermal compression is cooled and solidified, occurrence of the cracks is reduced.

In addition, according to the above-described manufacturing method, solder connection can be performed at a relatively low temperature (for example, a temperature such as 330° C. or lower, 300° C. or lower, 240° C. or lower, 200° C. or lower, 160° C. or lower, and 100° C. or lower). Therefore, it is possible to use a solder connection material having a low melting point such as 300° C. or lower, 280° C. or lower, 220° C. or lower, 180° C. or lower, 140° C. or lower, and 80° C. or lower. In addition, according to the above-described manufacturing method, solder connection can also be performed within a relatively short time (for example, short time of 3 minutes or shorter, 1 minute or shorter, 30 seconds or shorter, 15 seconds or shorter, and 10 seconds or shorter).

That is, according to the above-described manufacturing method, circuit connection can be performed with relatively low energy.

As the solder connection material that is used in the above-described manufacturing method, a known material that is used as solder can be widely used. The solder connection material may contain, for example, at least one kind selected from the group consisting of tin, a tin alloy, indium, and an indium alloy.

As the tin alloy, for example, an In—Sn alloy, an In—Sn—Ag alloy, an Sn—Au alloy, an Sn—Bi alloy, an Sn—Bi—Ag alloy, an Sn—Ag—Cu alloy, an Sn—Cu alloy, and the like can be used. As a specific example of the tin alloys, the following examples can be exemplified.
In—Sn (In: 52% by mass, Bi: 48% by mass, melting point: 118° C.)
In—Sn—Ag (In: 20% by mass, Sn: 77.2% by mass, Ag: 2.8% by mass, melting point: 175° C.)
Sn—Bi (Sn: 43% by mass, Bi: 57% by mass, melting point: 138° C.)
Sn—Bi—Ag (Sn: 42% by mass, Bi: 57% by mass, Ag: 1% by mass, melting point: 139° C.)
Sn—Ag—Cu (Sn: 96.5% by mass, Ag: 3% by mass, Cu: 0.5% by mass, melting point: 217° C.)
Sn—Cu (Sn: 99.3% by mass, Cu: 0.7% by mass, melting point: 227° C.)
Sn—Au (Sn: 21.0% by mass, Au: 79.0% by mass, melting point: 278° C.)

As the indium alloy, for example, an In—Bi alloy, an In—Ag alloy, and the like can be used. Specific examples of the indium alloy include the following examples.
In—Bi (In: 66.3% by mass, Bi: 33.7% by mass, melting point: 72° C.)
In—Bi (In: 33.0% by mass, Bi: 67.0% by mass, melting point: 109° C.)
In—Ag (In: 97.0% by mass, Ag: 3.0% by mass, melting point: 145° C.) Note that, the above-described indium alloy containing tin is classified into a tin alloy.

The solder connection material may contain at least one kind selected from the group consisting of an In—Bi alloy, an In—Sn alloy, an In—Sn—Ag alloy, an Sn—Au alloy, an Sn—Bi alloy, an Sn—Bi—Ag alloy, an Sn—Ag—Cu alloy, and an Sn—Cu alloy from the viewpoint capable of obtaining high reliability during a high-temperature and high-moisture test and a thermal impact test.

The tin alloy or the indium alloy may be selected in correspondence usage of the solder connection material (a temperature in use) or the like. For example, when employing the In—Sn alloy, and the Sn—Bi alloy, the electrodes can be fused together at a temperature of 150° C. or lower. In a case of employing a material with a high melting temperature such as the Sn—Ag—Cu alloy, the Sn—Cu alloy, and the like having a high melting point, even after being left at a high temperature, high reliability can be maintained.

The solder connection material may contain one or more kinds selected from Ag, Cu, Ni, Bi, Zn, Pd, Pb, Au, P, and B. In a case where the solder connection material contains Ag or Cu, the melting point of the solder connection material can be lowered to approximately 220° C., and joining strength with an electrode is further improved, and thus more satisfactory conduction reliability can be obtained.

The melting point of the solder connection material may be, for example, 300° C. or lower, 280° C. or lower, 220° C. or lower, 180° C. or lower, 160° C. or lower, 140° C. or lower, or 80° C. or lower from the viewpoint that mounting is possible at a low temperature. The melting point of the solder connection material is, for example, 70° C. or higher.

In addition, in this specification, the melting point of the solder connection material represents a temperature (first endothermic peak temperature) at which a first endothermic peak occurs when performing DSC measurement in an He gas flow at a temperature rising rate of 10° C./min by using differential scanning calorimeter (DSC).

The solder connection material may be, for example, a solder particle. An average particle size of the solder particle may be, for example, 1 to 500 μm. The average particle size of the solder particle may be 2 μm or greater, 3 μm or greater, 4 μm or greater, or 5 μm or greater from the viewpoint of easily obtaining excellent conductivity.

The average particle size of the solder particle may be 400 μm or less, 300 μm or less, 200 μm or less, or 100 μm or less from the viewpoint of easily obtaining satisfactory connection reliability to a micro-sized electrode. From the viewpoints, the average particle size of the solder particle may be 2 to 400 μm, 3 to 300 μm, 4 to 200 μm, or 5 to 100 μm.

The average particle size of the solder particle can be measured by using various methods in conformity to a size. For example, methods such as a dynamic light scattering method, a laser diffraction method, a centrifugal sedimentation method, an electrical sensing zone method, and a resonance-type mass measurement method can be used. Furthermore, a method in which the particle size is measured from an image obtained by an optical microscope, an electron microscope, or the like can be used.

Examples of a specific device include a flow type particle image analyzer, a micro-track, and a Coulter counter. The particle size of a solder particle that is not spherical may be the diameter of a circle circumscribing the solder particle in an SEM image.

The adhesive is, for example, a thermosetting adhesive having an insulating property. When using the insulating adhesive, the first circuit member and the second circuit member can be bonded to each other, and the periphery of the solder connection portion can be sealed with an insulating material. Therefore, the insulating adhesive can also be referred to as a sealing agent. The adhesive contains, for example, a thermosetting component (for example, a combination of a thermosetting resin and a curing agent, a combination of a polymerizable compound and a thermal polymerization initiator, and the like). The polymerizable compound may be, for example, a radical polymerizable compound. In this case, the thermal polymerization initiator may be a thermal radical polymerization initiator. The radical polymerizable compound may be a (meth)acrylic compound. Here, the (meth)acrylic compound represents a compound having one or more acryloyl group or methacryloyl group. Examples of the (meth)acrylic compound include urethane (meth)acrylate, isocyanuric acid modified bifunctional (meth)acrylate, and the like. The thermal radical polymerization initiator may be, for example, a peroxide. Examples of the peroxide include a peroxy ester such as 2,5-dimethyl-2,5-bis(2-ethylhexanoylperoxy)hexane. The adhesive may further contain a flux component such as phosphoric acid, succinic acid, glutaric acid, adipic acid, pimelic acid, suberic acid, benzoic acid, malic acid, or the like.

The adhesive may further contain a phosphoric ester-based organic compound for the purpose of increasing the activity of a solder particle surface and an electrode surface and improving an effect of realizing partial metallic joining between a solder particle interface and an electrode interface, and close contact and a wide contact interface with the solder particle. Examples of the phosphoric ester-based organic compound include compounds obtained by reacting phosphoric acid anhydride with 2-hydroxyethyl (meth)acrylate or a 6-hexanolide addition polymer thereof. The adhesive may further contain an inorganic filler such as silica filler, and a film forming material such as polyester urethane resin. A curing initiation temperature of the adhesive may be a temperature equal to or lower than the melting point of the solder connection material, or may be a temperature equal to or higher than the melting point of the solder connection material.

The first circuit member and the second circuit member may be the same as each other or different from each other. The first circuit member and the second circuit member may be a glass substrate or a plastic substrate (a plastic substrate consisting of an organic material such as polyimide, polycarbonate, polyethylene terephthalate, or cycloolefin polymer) on which a circuit electrode is formed; a printed wiring board; a ceramic wiring board; a flexible wiring board; an IC chip such as a driving IC; or the like. Specifically, the circuit members may be, for example, a printed wiring board (PWB) such as an FR-4 board, or may be a flexible printed circuit (FPC). The flexible printed circuit may be a flexible printed circuit (FPC for COF) used in a COF mounting method.

A combination of the first circuit member and the second circuit member is not particularly limited, and may be, for example, a combination in which the first circuit member is a printed wiring board (PWB) or a flexible printed circuit (FPC), and the second circuit member is a flexible printed circuit (FPC) (including an FPC for COF).

The first electrode is formed on a substrate (first substrate) constituting the first circuit member, and the second electrode is formed on a substrate (second substrate) constituting the second circuit member.

The first substrate and the second substrate are substrates formed from an inorganic material such as a semiconductor, glass, and ceramic, an organic material such as polyimide and polycarbonate, a composite such as glass/epoxy, or the like. Specifically, for example, in a case where the first circuit member is a printed wiring board, the first substrate may be a glass substrate, and in a case where the first circuit member is a flexible printed circuit, the first substrate may be a polyimide film substrate. Similarly, in a case where the second circuit member is a printed wiring board, the second substrate may be a glass substrate, and in a case where the second circuit member is a flexible printed circuit, the second substrate may be a polyimide film substrate. In addition, an insulating layer may be optionally disposed on one surface of the first substrate (a surface on which the first electrode is provided) and/or one surface of the second substrate (a surface on which the second electrode is provided).

The first electrode and the second electrode may be electrodes containing a metal such as gold, silver, tin, ruthenium, rhodium, palladium, osmium, iridium, platinum, copper, aluminum, molybdenum, titanium, and nickel, an oxide such as indium tin oxide (ITO), indium zinc oxide (IZO), and indium gallium zinc oxide (IGZO), or the like. The first electrode and the second electrode may be electrodes formed by laminating two or more kinds of the metals, the oxides, and the like. In this case, the first electrode and the second electrode may have a configuration of two layers, or a configuration of three or more layers.

Specifically, for example, one or both the first electrode and the second electrode may be electrodes (circuit electrodes) in which a nickel (Ni) coating layer and a gold (Au) coating layer are laminated in this order on a copper circuit (copper foil circuit), or electrodes (circuit electrodes) in which a gold (Au) plating layer is laminated on the copper circuit (copper foil circuit). In addition, one of the first electrode and the second electrode may be an electrode (circuit electrode) in which a nickel (Ni) plating layer and a gold (Au) plating layer are laminated in this order on the copper circuit (copper foil circuit), and the other may be an electrode in which an Sn plating layer is formed on the copper circuit (copper foil circuit) and the Sn plating layer is provided on the outermost surface.

The electrode including the Sn plating layer on the outermost layer may be used as an electrode of the FPC for COF.

The method for manufacturing the circuit connection structure of one embodiment can be performed by using, for example, a circuit connection device including a stage on which the first circuit member or the second circuit member is mounted, a pressing unit configured to press the first circuit member and the second circuit member in a direction of facing each other, a heating unit configured to heat at least one of the first circuit member and the second circuit member, and a cooling unit configured to cool between the first electrode and the second electrode in the step (d). The pressing unit and the heating unit may be integrated, and may be, for example, a heating and pressing tool. As the heating and pressing tool, a known heating and pressing tool that is used in conventional circuit connection can be used. The cooling unit may be, for example, an air cooling device, and the heating and pressing tool may have a cooling function.

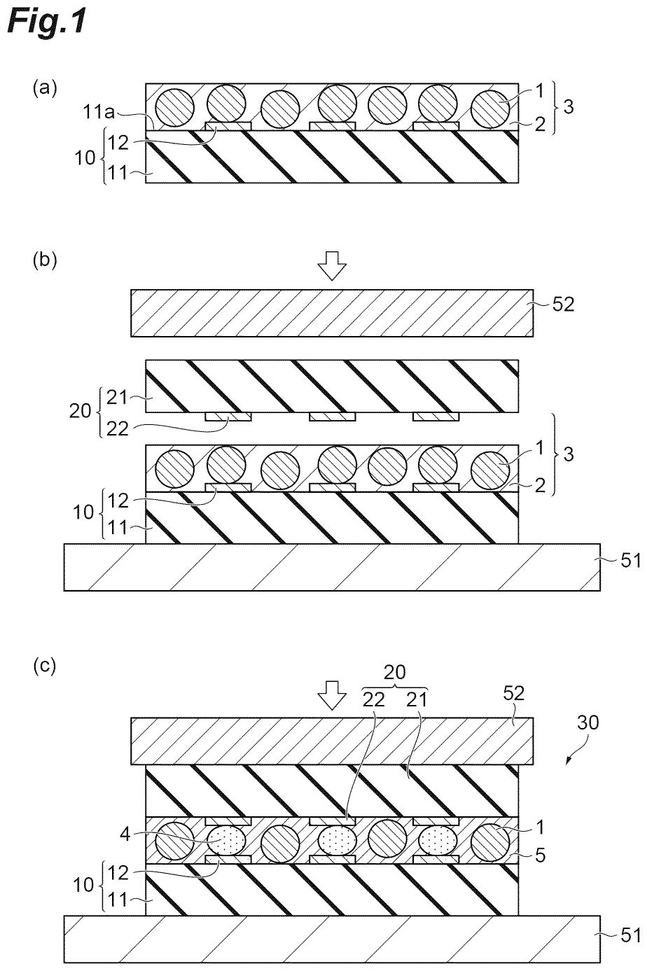

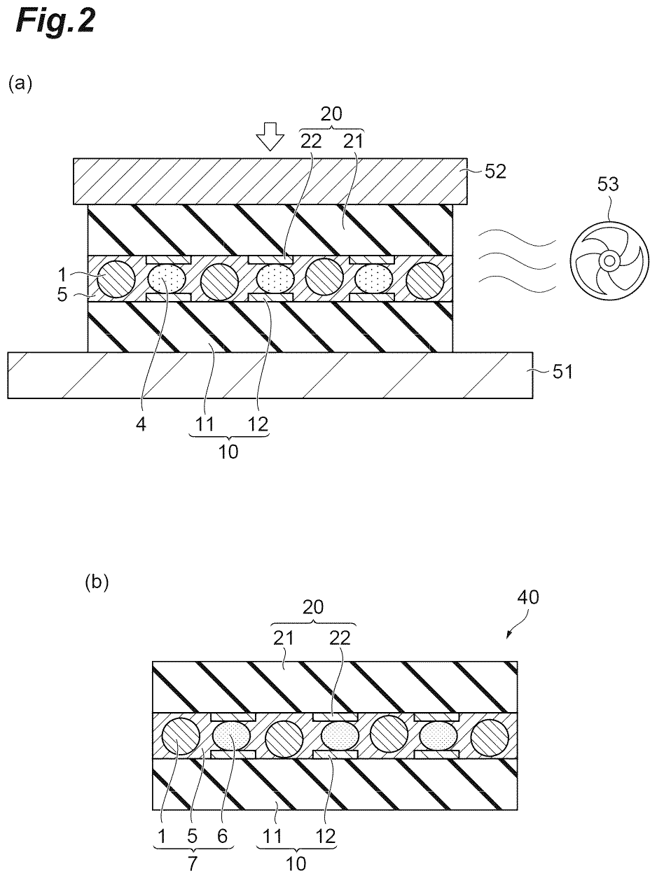

Hereinafter, respective steps in the method for manufacturing a circuit connection structure according to one embodiment will be described in more detail with reference to FIG. 1 and FIG. 2 by taking an aspect in which the solder connection material is a solder particle as an example.

### (Step (a))

In the step (a), a first circuit member 10 including a first base material 11 and a first electrode 12, and a circuit connection material 3 including a solder particle (solder connection material) 1 and an adhesive 2 are prepared, and the circuit connection material 3 is disposed on a surface (surface 11a of the first base material 11), on which the first electrode 12 is formed, of the first circuit member 10 (refer to (a) of FIG. 1).

In the step (a), the circuit connection material 3 may be disposed on the first circuit member 10 in a state of film containing the solder particle 1 and the adhesive 2, or may be disposed on the first circuit member 10 in a state of paste containing the solder particle 1 and the adhesive 2. In a case where the circuit connection material 3 is a film (for example, an anisotropic conductive adhesive film) containing the solder particle 1 and the adhesive 2, the circuit connection material 3 can be disposed on the first circuit member 10 by lamination. In addition, after disposing the film-shaped circuit connection material 3 on the first circuit member 10, the circuit connection material 3 and the circuit member 10 may be compressed to each other by applying a pressure to the circuit connection material 3. At this time, the circuit connection material 3 may be heated at a low temperature at which curing of the adhesive 2 does not proceed.

The circuit connection material 3 may be in a paste state (liquid) or a solid state at 25° C. Here, description of “the circuit connection material 3 is in a paste state at 25° C.” represents that the viscosity of the circuit connection material 3 at 25° C., which is measured by an E-type viscometer, is 400 Pa-s or less. In a case where the circuit connection material 3 is in the paste state at 25° C., it is possible to dispose the circuit connection material 3 on the first circuit member 10 by applying the circuit connection material 3 onto the first circuit member as is. In a case where the circuit connection material 3 is in the solid state at 25° C., the circuit connection material 3 may be used after being converted into the paste state through heating, or after being converted into the paste state by using a solvent. The solvent that can be used is not particularly limited as long as the solvent is not reactive with components in the adhesive, and has sufficient solubility.

### (Step (b))

In the step (b), the first circuit member 10 is disposed on a stage 51, a second circuit member 20 including a second base material 21 and a second electrode 22 is disposed on the first circuit member 10 so that the first electrode 12 and the second electrode 22 face each other (refer to (b) of FIG. 1). At this time, the second circuit member 20 may be disposed on the stage 51, and the first circuit member 10 may be disposed on the second circuit member 20 so that the first electrode 12 and the second electrode 22 face each other.

In (b) of FIG. 1, the circuit connection material 3 and the second circuit member 20 are spaced apart from each other, but the circuit connection material 3 may be brought into contact with the second circuit member 20 to obtain a laminated body. In addition, in FIG. 1, the step (b) is performed after the step (a), but the order of performing the step (a) and the step (b) is not particularly limited.

### (Step (c))

In step (c), in a state in which the solder particle 1 is interposed between the first electrode 12 and the second electrode 22, the first circuit member 10 and the second circuit member 20 are thermally compressed at a temperature equal to or higher than the melting point of the solder particle (refer to (b) and (c) of FIG. 1).

Step (c) includes, for example, a step of heating between the first electrode 12 and the second electrode 22 at a temperature equal to or higher than the melting point of the solder particle, and a step of pressing between the first electrode 12 and the second electrode 22 in a facing direction thereof. When a temperature and a state between the first electrode 12 and the second electrode 22 are maintained at a temperature equal to or higher than the melting point of the solder particle, and in a pressed state, the first circuit member 10 and the second circuit member 20 are thermally compressed, and thus a compressed body 30 is obtained.

The above-described heating and pressing may be performed by heating and pressing one or both the first circuit member 10 and the second circuit member 20. For example, as illustrated in (c) of FIG. 1, heating and pressing may be performed by pressing a heating and pressing tool 52 against the second circuit member 20 to press the second circuit member 20 to the first circuit member 10 side (direction indicated by an arrow in (c) of FIG. 1), or heating and pressing may be performed by pressing the heating and pressing tool 52 against the first circuit member 10 to press the first circuit member 10 to the second circuit member 20 side.

Heating and pressing timing is not particularly limited, and heating and pressing may be started simultaneously, pressing may be started before starting heating, or pressing may be started after starting heating. In the step (c), heating may be started before obtaining the above-described laminated body. For example, after the step (a), the step (b) may be performed after heating of the circuit member disposed on the stage is started.

A temperature (thermal compression temperature) during the thermal compression is a temperature equal to or higher than the melting point of the solder connection material, and may be a temperature equal to or higher than a curing initiation temperature of the adhesive. The thermal compression temperature may be set in correspondence with the melting point of the solder connection material. For example, in a case where the melting point of the solder connection material is 300° C. or lower, 280° C. or lower, 240° C. or lower, 200° C. or lower, 160° C. or lower, or 80° C. or lower, the thermal compression temperature can be set to 330° C. or lower, 300° C. or lower, 280° C. or lower, 240° C. or lower, 200° C. or lower, or 100° C. or lower, respectively. A lower limit value of the thermal compression temperature may be, for example, a temperature higher than the melting point of the solder connection material by 10° C. or higher. The thermal compression temperature may be, for example, 80 to 330° C., 100 to 270, 140 to 230° C., or 140 to 200° C. Here, the thermal compression temperature is a temperature between the first electrode 12 and the second electrode 22 reached when performing thermal compression for predetermined seconds, and is a value that is confirmed by the method described in the examples.

A pressing force during the thermal compression may be 0.01 to 100 MPa, 0.1 to 20 Pa, or 0.5 to 10 Pa. Here, the pressing force during the thermal compression is a pressing force per unit area when performing the thermal compression for predetermined seconds, and is a value that is confirmed by a setting value of a compression device. In addition, the pressing force during the thermal compression is not necessarily constant, and may fluctuate within the above-described range.

A thermal compression time may be 1 to 1800 seconds, 2 to 60 seconds, or 3 to 30 seconds. Here, the thermal compression time is time from the initiation of both heating and pressing until the initiation of cooling in a step (d). Note that, initiation of cooling in the step (d) represents the time when cooling is initiated by using the cooling unit in the step (d), and when cooling in the step (d) is natural cooling, it represents the time when heating is stopped. In addition, in a case where the cooling in the step (d) is performed by changing a setting temperature of the thermal compression tool so that the temperature of the solder connection material when terminating cooling becomes a temperature equal to or lower than the melting point of the solder connection material, the time when the setting temperature of the thermal compression tool is changed is set as the initiation of cooling in the step (d). In a case of using changing of the setting temperature of the thermal compression tool and cooling using the cooling unit in combination, a point of time when any one of cooling is initiated is set as the initiation of cooling.

The compressed body 30 obtained in the step (c) includes a melt 4 of the solder particle between the first electrode 12 and the second electrode 22. In addition, the compressed body 30 includes a region (cured material region) 5 consisting of a cured material of the adhesive 2 between the first circuit member 10 and the second circuit member 20. Although not illustrated in the drawing, an uncured adhesive 2 may be included in the cured material region 5. The adhesive may not be completely cured in the step (c). For example, curing of the adhesive may be completed in a step (d) or a step (e) to be described later.

### (Step (d))

In the step (d), the first electrode 12 and the second electrode 22 are cooled while applying a pressure between the first electrode 12 and the second electrode 22 until a temperature between the first electrode 12 and the second electrode 22 becomes a temperature equal to or lower than the melting point of the solder particle 1 from a temperature equal to or higher than the melting point of the solder particle 1 (refer to (a) of FIG. 2).

Cooling may be performed by natural cooling between the first electrode 12 and the second electrode 22 after stopping heating between the first electrode 12 and the second electrode 22 (heating for the compressed body 30), but a cooling unit may be used from the viewpoint of production efficiency. Specifically, for example, as illustrated in (a) of FIG. 2, cooling (for example, air cooling) between the first electrode 12 and the second electrode 22 may be performed by using a cooling device (for example, an air-cooling device) 53.

Although depending on a cooling method, cooling time may be, for example, 0.5 to 1800 seconds, 1.0 to 600 seconds, or 2.0 to 150 seconds. The step (d) may be performed continuously from the step (c).

That is, after a pressure is applied between the first electrode 12 and the second electrode 22 in the step (c), cooling in the step (d) may be performed while remaining the pressure without release. For example, in a case of performing pressing in the step (c) by using the heating and pressing tool 52, the heating and pressing tool 52 is pressed against the circuit member (the first circuit member 10 or the second circuit member 20), and then the circuit member may be pressed continuously by the heating and pressing tool 52 until a temperature between the first electrode 12 and the second electrode 22 becomes a temperature equal to or lower than the melting point of the solder particle 1 to maintain a pressing state between the first electrode 12 and the second electrode 22.

A pressing force in the step (d) may be the same as the range exemplified as the pressing force during thermal compression in the step (c). Pressing in the step (d) may be performed at a pressing force lower than the pressing force during thermal compression in the step (c). The pressing force in the step (d) may be, for example, 0.01 to 100 MPa.

Pressing in the step (d) may be terminated immediately after the temperature between the first electrode 12 and the second electrode 22 becomes a temperature equal to or lower than the melting point of the solder connection material, or may be performed continuously until the temperature between the first electrode 12 and the second electrode 22 becomes a temperature close to an ordinary temperature (for example, 50° C. or lower). In a case where pressing is terminated at a temperature sufficiently higher than the ordinary temperature (for example, 100 to 270° C.), the step (e) of cooling without applying pressure between the first electrode 12 and the second electrode 22 may be performed.

Cooling in the step (e) may be performed in a similar manner as in the cooling in the step (d).

According to the above-described method, a circuit connection structure 40 shown in (b) of FIG. 2 is obtained. The circuit connection structure 40 includes the first circuit member 10, the second circuit member 20, and a circuit connection portion 7 that is disposed between the first circuit member 10 and the second circuit member 20, bonds the first circuit member 10 and the second circuit member 20, and electrically connects the first electrode 12 and the second electrode 22 to each other.

For example, the circuit connection structure 40 may be a circuit connection structure for a display input circuit, a semiconductor package, or a semiconductor sensor, or may be a circuit connection structure as a connector replacement circuit.

The circuit connection portion 7 includes a region (cured material region) 5 consisting of a cured material of the adhesive 2, and a solder connection portion 6 as an electrode connection portion between facing electrodes. The solder connection portion 6 is formed by melting and solidifying the solder particle 1, comes into close contact and wide physical contact with surfaces of the first electrode 12 and the second electrode 22 to form partial metal joining. In the circuit connection portion 7, the cured material region 5 is formed at the periphery of the solder connection portion 6, and the solder connection portion 6 is sealed by the cured material of the adhesive 2. As illustrated in (b) of FIG. 2, a solder particle 1 (or a melted and solidified material thereof) that is not used for connection may be contained in the cured material region 5.

Hereinbefore, the method for manufacturing a circuit connection structure according to the first embodiment has been described with reference to the example using the method for manufacturing the circuit connection structure using the solder particle as the solder connection material, but the method for manufacturing a circuit connection structure according to the present disclosure is not limited to the above method.

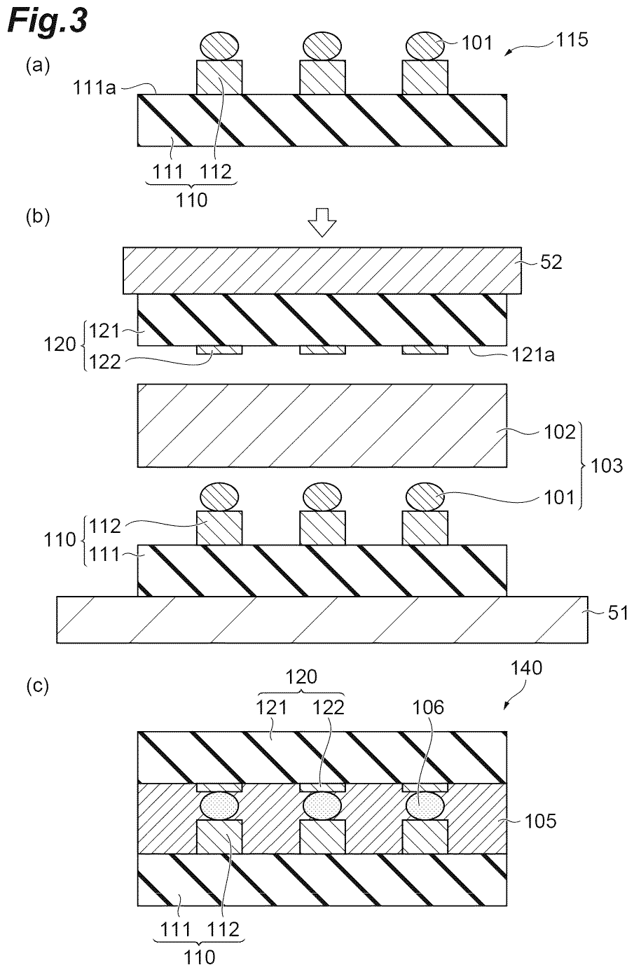

For example, the solder connection material may be a solder bump. FIG. 3 is a cross-sectional view schematically illustrating a method for manufacturing a circuit connection structure using a solder bump as the solder connection material. In the method in which the solder bump is used as the solder connection material, first, a solder bump-attached circuit member 115 in which a solder bump 101 is formed on a first electrode 112 of a first circuit member 110 (refer to (a) of FIG. 3) is prepared. Next, an adhesive 102 and a second circuit member 120 are disposed on a surface, on which the solder bump 101 is formed, of the solder bump-attached circuit member 115 (refer to (b) of FIG. 3). At this time, the second circuit member 120 is disposed so that the first electrode 112 and a second electrode 122 face each other through the adhesive 102. According to this, a step (a) of disposing a circuit connection material 103 including the solder bump 101 and the adhesive 102 as a solder connection material on a surface (surface 111a of a first base material 111), on which the first electrode 112 is formed, of the first circuit member 110, and a step (b) of disposing the second circuit member 120 on the first circuit member 110 so that the first electrode 112 and the second electrode 122 face each other are terminated. Next, a step (c), a step (d), and, optionally, a step (e) are performed in a similar manner as in the case of using the solder particle, thereby obtaining a circuit connection structure 140 shown in (c) of FIG. 3.

For example, the solder bump 101 can be formed by heating (optionally heating and pressing) a solder particle on the first electrode 112 to be melted, and by cooling and solidifying the molten solder particle.

The adhesive 102 may be used in a film state or a paste state. A method of disposing the adhesive 102 on the first circuit member 110 is not particularly limited. For example, in a case where the adhesive 102 is in a film state, the adhesive 102 may be disposed on the solder bump-attached circuit member 115 by lamination. In addition, in a case where the adhesive 102 is in a paste state at 25° C., the adhesive 102 may be disposed on the first circuit member 10 by applying the adhesive 102 as is onto the solder bump-attached circuit member 115. In a case where the adhesive 102 is in a solid state at 25° C., the adhesive 102 may be used after being converted into the paste state through heating, or after being converted into the paste state by using a solvent. The solvent that can be used is not particularly limited as long as the solvent is not reactive with components in the adhesive, and has sufficient solubility.

The adhesive 102 may be disposed in advance on a surface (surface 121a of a second base material 121), on which the second electrode 122 is formed, of the second circuit member 120. In this case, the step (a) is completed by performing the step (b).

In the method illustrated in FIG. 3, the adhesive 102 is disposed on the solder bump-attached circuit member 115, but the solder bump 101 may be formed after disposing the adhesive 102 on the first circuit member 110.

### EXAMPLES

Hereinafter, the present disclosure will be described in detail on the basis of examples, but the present disclosure is not limited to the examples.

### Example 1

### (Preparation Step)

### [Preparation of Solder Particle]

Solder particles manufactured by MITSUI MINING & SMELTING CO., LTD. (product name: Sn72Bi28 Type5) were classified to remove solder particles with a particle size of 15 μm or less and solder particles with a particle size of 25 μm or more, thereby obtaining solder particles A (Bi content: 28% by mass, Sn content: 72% by mass, average particle size: 20 μm, melting point: 139° C.). The average particle size of the solder particles A was confirmed by measuring a D50 value of the solder particles A with a microtrack measuring device. The melting point of the solder particles was calculated from a value of a first endothermic peak in DSC. DSC measurement of the solder particles was performed by using a differential scanning calorimeter manufactured by TA Instruments, Inc. (product name: Q-1000) at a temperature rising rate of 10° C./min in a He gas flow in a range of 30 to 200° C.

### [Preparation of Coating Solution]

5 parts by mass of urethane acrylate (product name: UN-952, manufactured by Negami chemical industrial co., ltd.) and 10 parts by mass of isocyanuric acid EO-modified diacrylate (product name: M-215, manufactured by TOAGOSEI CO., LTD.) which are radical polymerizable compounds, 2 parts by mass of reaction product of a 6-hexanolide addition polymer of 2-hydroxyethyl methacrylate and phosphoric acid anhydride (product name: PM-21, manufactured by Nippon Kayaku Co., Ltd.) which is a phosphoric ester-based organic compound, 3 parts by mass of peroxy ester (product name: Perhexa 250, manufactured by NOF CORPORATION) which is a thermal radical generator, 15 parts by mass of silica filler (product name: AEROSIL R202, manufactured by NIPPON AEROSIL CO., LTD.) which is an inorganic filler, and 35 parts by mass of polyester urethane resin (product name: UR8240, manufactured by TOYOBO CO., LTD.) which is a film-forming material were mixed and stirred in methyl ethyl ketone to obtain a solution A.

The obtained solder particles A were dispersed in the solution A. At this time, the amount of the solder particles A added was set to 30 parts by mass with respect to 100 parts by mass of non-volatile matters (components other than methyl ethyl ketone) in the solution A. According to this, a coating solution for forming a film-shaped circuit connection material was obtained.

### [Formation of Film-Shaped Circuit Connection Material]

The coating solution obtained as described above was applied to a polyethylene terephthalate (PET) film (thickness: 50 μm) with one surface subjected to a release treatment by using a coating device. A coated film was dried by hot air drying at 70° C. to form an anisotropic conductive film-shaped circuit connection material (thickness: 25 μm) on the PET film, thereby obtaining a peelable base material-attached film-shaped circuit connection material. Note that, the thickness of the film-shaped circuit connection material was measured by a laser microscope. Specifically, a part of the film-shaped adhesive on the PET film was removed, a height from an exposed portion of a surface of the PET film to a surface of the film-shaped adhesive was measured to obtain the thickness of the film-shaped circuit connection material.

### (Step (a))

A first circuit member provided with a gold electrode (10 mm×5 mm, single electrode) on a surface of a ceramic substrate was prepared as an adherend resembling a circuit member. Next, the peelable base material-attached film-shaped circuit connection material obtained above was cut to a width of 1.5 mm and was attached to the gold electrode of the first circuit member from the film-shaped circuit connection material side. Next, the film-shaped circuit connection material and the first circuit member were thermally compressed by using a thermal compression device (heating method: constant heat type, manufactured by Nikka Setsubi Engineering Co., Ltd.) to obtain a laminated body in which the film-shaped circuit connection material was provided on the first circuit member. Specifically, the first circuit member to which the peelable base material-attached film-shaped circuit connection material was attached was placed on a stage with a PET film side facing up, and the film-shaped circuit connection material was heated and pressed by pressing a heating and pressing tool against the PET film. Thermal compression time (pressing time) was set to 1 second, and a pressing force was set to 1 MPa per total area (area of an adhesive portion) of the film-shaped circuit connection material. A temperature of the heating and pressing tool was adjusted so that a temperature of the film-shaped circuit connection material reached 70° C. The reached temperature of the film-shaped circuit connection material was measured by inserting a thermocouple into the film-shaped circuit connection material. The PET film was peeled after the laminated body was returned to an ordinary temperature (25° C.).

### (Step (b))

As the second circuit member, a flexible printed circuit (FPC) including a circuit electrode formed by subjecting a copper circuit having a line width of 100 μm, a pitch of 200 μm, and a thickness of 35 μm to a Ni/Au plating treatment was prepared. Next, the second circuit member was placed on the laminated body obtained as described above so that the gold electrode of the first circuit member and the circuit electrode of the second circuit member face each other, thereby obtaining a laminated body in which the film-shaped circuit connection material and the second circuit member were provided on the first circuit member.

### (Step (c))

Next, the first circuit member and the second circuit member were thermally compressed by using a thermal compression device (heating method: pulse heat type, manufactured by OHASHI ENGINEERING CO., LTD.). Specifically, the laminated body obtained in step (b) was placed on a stage with the second circuit member side facing upward, and the heating and pressing tool was pressed against the second circuit member to heat and press the second circuit member. Thermal compression time (time from when the heating and pressing tool come into contact with the second circuit member to when the cooling in step (d) was initiated) was set to 8 seconds, and a pressing force was set to 1 WPa per total area (area of an adhesive portion) of the film-shaped circuit connection material. A temperature of the heating and pressing tool was adjusted so that a temperature reached between the opposing electrodes reached 155° C. The temperature reached between the opposing electrodes was measured by inserting a thermocouple into the film-shaped circuit connection material.

### (Step (d))

Next, while the heating and pressing tool was pressed against the second circuit member, the heating by the heating and pressing tool was stopped and the compressed body was cooled (for example, air cooling). The pressing force during cooling was set to 1 WPa per total area (area of the adhesive portion) of the film-shaped circuit connection material. When the temperature between the opposing electrodes was lowered to 120° C., the heating and pressing tool was removed from the second circuit member. Time required until the temperature between the opposing electrodes reached 120° C. after starting cooling was 50 seconds.

### (Step (e))

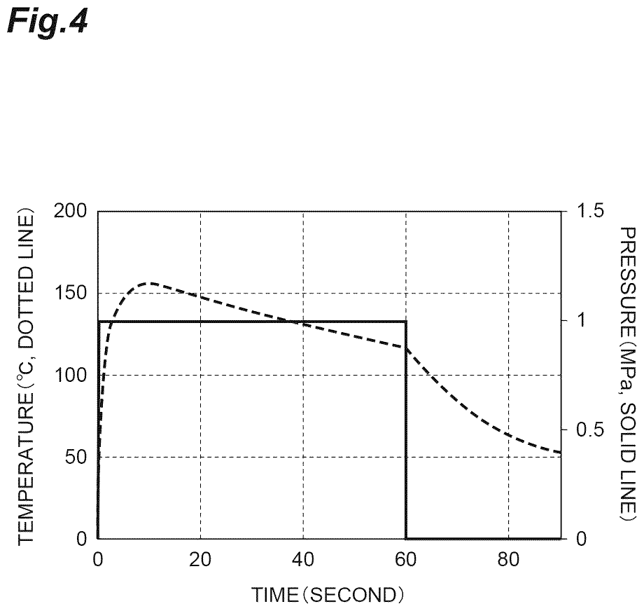

Cooling in the step (d) was continued until the temperature between the opposing electrodes reached a temperature close to an ordinary temperature (50° C. or lower), thereby obtaining the circuit connection structure of Example 1. A graph (temperature-pressure profile) showing a relationship between time from the start of heating and pressing in the step (c) until obtaining the circuit connection structure, and the temperature between the electrodes and the pressing force is shown in FIG. 4. Note that, the temperature profile in FIG. 4 shows actual measured values, and the pressure profile shows device setting values.

### Comparative Example 1

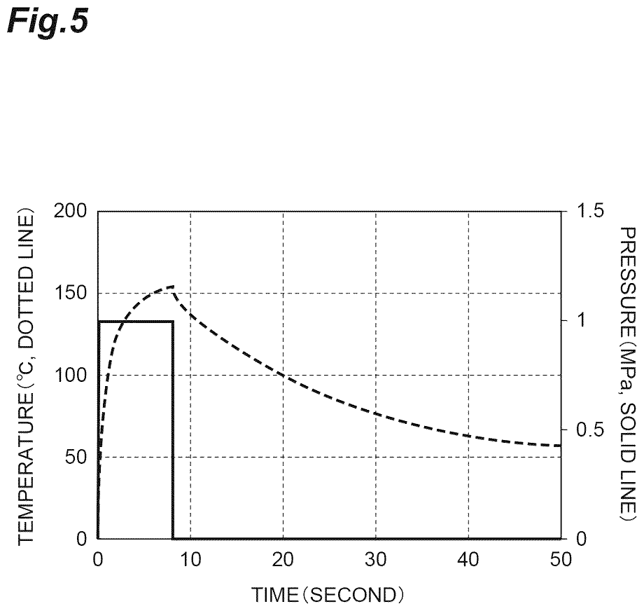

After performing the preparation step to the step (c) in a similar manner as in Example 1, the heating and pressing tool was separated from the second circuit member after passage of 8 seconds after the heating and pressing tool came into contact with the second circuit member to terminate the thermal compression without performing a step (d) and a step (e), and the compressed body was left as is at an ordinary temperature (25° C.) to be cooled, thereby obtaining a circuit connection structure of Comparative Example 1. A graph (temperature-pressure profile) showing a relationship between time from the start of heating and pressing in step (c) until obtaining the circuit connection structure, and the temperature between electrodes and the pressing force is shown in FIG. 5.

### Comparative Example 2

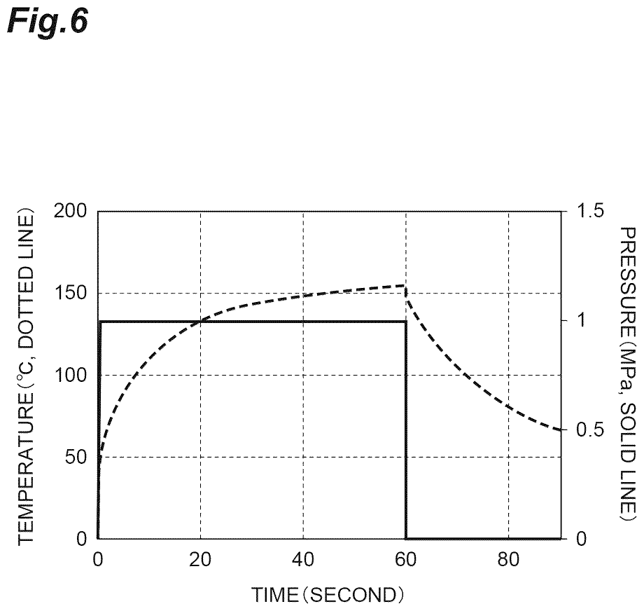

A circuit connection structure of Comparative Example 2 was obtained in a similar manner as in Comparative Example 1 except that the thermal compression time (time during which the heating and pressing tool was in contact with the second circuit member) in step (c) was changed to 60 seconds. A graph (temperature-pressure profile) showing a relationship between time from the start of heating and pressing in step (c) until the circuit connection structure was obtained, and the temperature between electrodes and the pressing force is shown in FIG. 6.

### <Evaluation>

Presence or absence of cracks in the inter-electrode connection portion (solder connection portion) in the circuit connection structures prepared in Example 1 and Comparative Examples 1 and 2 was confirmed. Specifically, first, the circuit connection structure was sandwiched between two pieces of glass (thickness: approximately 1 mm), and a resin composition consisting of 100 g of bisphenol A type epoxy resin (product name: JER811, manufactured by Mitsubishi Chemical Corporation) and 10 g of curing agent (product name: Epomount curing agent, manufactured by Refine Tec Ltd.) was cast. Next, the cast was polished by using a polishing machine to expose a cross-section including the inter-electrode connection portion parallel to a connection direction of the circuit connection structure. Next, the exposed cross-section was observed by using a scanning electron microscope (SEM, product name: SE-8020, manufactured by Hitachi High-Tech Science Corporation) to observe the presence or absence of cracks in the inter-electrode connection portion. In a case where there was a crack with a length of 30% or greater relative to the particle size of the solder particle observed in the cross-sectional observation, it was determined that there was a crack. As a result, cracks were observed in Comparative Examples 1 and 2, but cracks were not observed in Example 1.

### REFERENCE SIGNS LIST

1: solder particle (solder connection material), 2, 102: adhesive, 3, 103: circuit connection material, 5: cured material region, 6: solder connection portion, 10, 110: first circuit member, 11, 111: first base material, 11a, 111a: surface of first base material (surface on which first electrode of first circuit member is formed), 12, 112: first electrode, 20, 120: second circuit member, 21, 121: second base material, 22, 122: second electrode, 30: compressed body, 40, 140: circuit connection structure, 51: stage, 52: heating and pressing tool, 53: cooling device, 101: solder bump (solder connection material), 115: solder bump-attached circuit member.

1. A method for manufacturing a circuit connection structure, comprising:
a step (a) of disposing a circuit connection material comprising a solder connection material and an adhesive on a surface, on which a first electrode is formed, of a first circuit member having the first electrode;
a step (b) of disposing a second circuit member having a second electrode on the first circuit member so that the first electrode and the second electrode face each other;
a step (c) of thermally compressing the first circuit member and the second circuit member at a temperature equal to or higher than a melting point of the solder connection material in a state in which the solder connection material is interposed between the first electrode and the second electrode; and
a step (d) of cooling while applying a pressure between the first electrode and the second electrode until a temperature between the first electrode and the second electrode becomes a temperature equal to or lower than the melting point of the solder connection material from a temperature equal to or higher than the melting point of the solder connection material.

2. The method for manufacturing a circuit connection structure according to claim 1,
wherein the solder connection material is a solder particle.

3. The method for manufacturing a circuit connection structure according to claim 2,
wherein in the step (a), the circuit connection material is disposed on the first circuit member in a state of film comprising the solder particle and the adhesive.

4. The method for manufacturing a circuit connection structure according to claim 2,
wherein in the step (a), the circuit connection material is disposed on the first circuit member in a state of paste comprising the solder particle and the adhesive.

5. The method for manufacturing a circuit connection structure according to claim 1,
wherein the melting point of the solder connection material is 300° C. or lower, and
the thermal compression temperature in the step (c) is 330° C. or lower.

6. A circuit connection device that is used in the method for manufacturing a circuit connection structure according to claim 1, comprising:
a stage on which the first circuit member or the second circuit member is mounted;
a pressing unit configured to press the first circuit member and the second circuit member in a direction of facing each other;
a heating unit configured to heat at least one of the first circuit member and the second circuit member; and
a cooling unit configured to cool between the first electrode and the second electrode in the step (d).
